(19) United States
(12) Patent Application Publication
(10) Pub. No.: US 2013/0062210 A1
(43) Pub. Date: Mar. 14, 2013

(54) MANUFACTURING METHOD OF SUBSTRATE AND MANUFACTURING METHOD OF WIRING SUBSTRATE

(71) Applicants: Takashi FUSHIE, Shinjuku-ku (JP); Hajime KIKUCHI, Shinjuku-ku (JP)

(72) Inventors: Takashi FUSHIE, Shinjuku-ku (JP); Hajime KIKUCHI, Shinjuku-ku (JP)

(73) Assignee: HOYA CORPORATION, Tokyo (JP)

(21) Appl. No.: 13/610,359

(22) Filed: Sep. 11, 2012

(30) Foreign Application Priority Data
Sep. 13, 2011 (JP) 2011-199614
Sep. 16, 2011 (JP) 2011-203327
Sep. 16, 2011 (JP) 2011-203328
Aug. 10, 2012 (JP) 2012-178893
Aug. 10, 2012 (JP) 2012-178894
Aug. 10, 2012 (JP) 2012-178895

(51) Int. Cl. H05K 3/00; C25D 5/18

(52) U.S. Cl. 205/103; 205/125

(57) ABSTRACT

Manufacturing methods of a substrate and a wiring substrate include a step A of forming a primary plating layer on a lower side of a glass substrate having a through-hole; a step B of sealing a lower opening of the through-hole by forming a first layer on an upper side using electroplating; and a step C of filling the through-hole by depositing a second layer in the through-hole using electroplating from the upper side. In the step A, the primary plating layer is formed on from a lower opening edge to a partial sidewall surface of the through-hole. In the step B, the lower opening is sealed by growing the first layer from a primary plating layer surface inside the through-hole. In the step C, the through-hole is filled with plating metal by growing the second layer from a first layer surface inside the through-hole toward an upper opening.

### BACKGROUND OF THE INVENTION

1. Field of the Invention

The present invention relates to a manufacturing method of a substrate using a glass base material and a manufacturing method of a wiring substrate.

2. Description of the Related Art

In recent years, for example, with respect to a wiring substrate mounted with electronic components such as MEMS (Micro Electro Mechanical System), there is a demand for enabling high-density mounting of electronic devices and so on with ensuring connection reliability. In response to this demand, the present inventors have proposed the following manufacturing method of substrate. In the method, with respect to the wiring substrate, not a resin substrate, a glass substrate which has good properties such as smoothness, hardness, insulation and heat resistance is used as a core substrate and a wiring substrate is obtained by filling a through-hole formed on the glass substrate with metal; thus the wiring substrate is available as a double-sided wiring substrate (for example, referring to patent document 1).

In the patent document 1, the manufacturing method of the substrate includes a step of forming the through-hole on the glass substrate and a step of filling the through-hole with metal by plating method (electroplating) is proposed. Of the steps, in the earlier stage of the step of filling the through-hole with metal, either one of opening parts of the through-hole in front and rear surfaces of the glass substrate is sealed with metal, after that, the through-hole is filled with metal by depositing metal from the sealed opening part toward the other opening part. Specifically, in a set of steps in the manufacturing method of the substrate, steps shown in FIGS. 13A to 13D are adopted.

In the step shown in FIG. 13A, primary plating layer 53 which has a three-layer structure is formed on the lower surface side of the glass substrate 52 with through-hole 51 by stacking a chromium layer 53a, a chromium-copper layer 53b and a copper layer 53c in sequence using sputtering. Next, in the step shown in FIG. 13B, the one (lower) opening part of the through-hole 51 is sealed with a plating layer by forming the plating layer 54 on the lower surface side of the glass substrate 52 using electroplating. After that, in the step shown in FIGS. 13C and 13D, the through-hole is filled with the plating layer 54 by growing the plating layer 54 using the electroplating from an upper surface side of the glass substrate 52.

Patent document 1: WO2005/027605

### BRIEF SUMMARY OF THE INVENTION

However, in the above conventional manufacturing method of the substrate, there were the following problems. After sealing the one opening part of the through-hole 51 with metal (plating layer 54), in the case of filling the through-hole 51 by growth of the plating layer 54, almost all areas through the one opening part to the other opening part of the through-hole 51, i.e., through total depth size of the through-hole 51 (thickness T of the glass substrate 52), growth of metal in plating is needed.

The growth in plating becomes faster in an area where concentration of metal ions is high. This is because high current density of metal deposition can be obtained. On the other hand, as electrodeposition makes progress, a localized difference in consumption of metal ions arises in the plating bath; as a result, a difference in concentration of metal ions arises. Depending on the shapes of the through-holes 51 and the surface environment of the substrate with the through-holes 51 formed, an area where concentration of metal ions becomes low may be generated; as a result, the current density decreases in the area and growth in plating becomes slow.

For example, in the case where a hole diameter of the through-hole 51 is small along with finer wiring, when metal ions in the plating bath become hard to go into through-holes 51, growth rate of plating decreases in the through-holes 51, which leads to a problem in that it takes more time to finish filling the through-holes with metal.

Also, when the one opening part of the through-hole 51 is sealed by plating, inside the hole, a difference in concentration of metal ions arises in the vicinity of the sealed opening part and the other opening part. In this case, before filling the inside of the through-hole with metal, metals deposited near around the periphery of the other opening part grow to connect each other; as a result, a void may be formed inside the through-hole 51.

Further, in the case of a substrate where a plurality of the through-holes is formed, variations in concentration of metal ions are easy to be generated between an area where distribution density of the through-holes 51 is sparse and an area where distribution density of the through-holes 51 is dense. This is because consumption of metal ions in the dense area is larger than that in sparse area. Variations in concentration of metal ions lead to variations in growth rate of plating; as a result, variations in the degree of filling the hole with metal arise in each area on the substrate.

The present invention has been achieved in view of the above problems relevant to the concentration distribution of metal ions when performing the electroplating, and an object of the present invention is to provide a manufacturing method of substrate and a manufacturing method of wiring substrate which are capable of avoiding the variations in the degree of filling the through-hole with metal and the variations in the degree of filling with metal between the through-holes without a decrease in productivity resulting from making processes more complicated and so on.

A manufacturing method of a substrate disclosed in the specification includes a first step of preparing a glass substrate comprising a plate glass base material having a first surface and a second surface which have a relation of front and rear surfaces, wherein one or more through-holes having a first opening part at a first surface side and a second opening part at a second surface side is formed on the glass substrate; a second step of forming a primary plating layer composed of metal on the first surface side of the glass substrate; a third step of sealing the first opening part of the through-hole with a first metal material by forming a layer of the first metal material using an electroplating on the first surface side of the glass substrate; and a fourth step of filling the through-hole with metal by depositing a second metal material in the through-hole using the electroplating from the second surface side of the glass substrate.

In the manufacturing method of the substrate, in the second step, the primary plating layer is also formed on a part of a sidewall at a first opening part side of the through-hole. In the next third step, the first opening part of the through-hole is sealed with the first metal material by making metal electrodeposited from the primary plating layer located on the sidewall; thereby the through-hole becomes the hole with a thick bottom, looking from the second opening part. In the fourth step, it is characteristic that the hole is filled with metal by making the second metal material deposited from the bottom of the hole, i.e. the sealed portion of the first opening part.

According to the manufacturing method, the first metal material is also electrodeposited from the primary plating layer located on the sidewall part of the through-hole. When the first metal material is grown by plating from the sidewall part, the first opening part is sealed by a thick metal layer. Looking at the hole from the second opening part, the through-hole has a thick bottom since the first opening part is thickly sealed with metal. Metal ions in electrolyte solution become easy to go into the first metal material layer and the decrease of concentration of metal ions relevant to the growth of second metal material by plating is suppressed. As a result, growth rate of the second metal material in plating is maintained and filling of the through-hole with metal makes progress effectively.

In the manufacturing method of the substrate, in at least a part of the forth step, it is preferable that a pulse plating in which a positive forward current and a negative reverse current is alternately applied is performed.

An area appears where current density of the electroplating is different depending on positions of the inside of the through-hole and positions with the through-hole formed. When flowing only positive forward current and making metal electrodeposited, growth in plating in the area where the current density is ensured to be high becomes fast; however, growth in plating inside of the through-hole which is an area where the current density is low becomes slow. As a result, the dense filling of the metal in the through-hole may not make progress. As shown in the configuration, by flowing current sometimes backwardly by the pulse plating, it is possible to ionize extra deposited metal in the area with high current density and return the metal to the electrolyte solution again. As a result, the concentration of metal ions in the electrolyte solution can be maintained and the variations in the degree of the growth in plating resulting from the shape of the through-hole and the place where the through-hole is formed on, can be suppressed.

In the manufacturing method of the substrate, when the pulse plating is performed, it is preferable that the reverse current at a predetermined value is applied after the forward current at a predetermined value is applied.

An amount of electrodeposited metal by electroplating is proportional to an electrical quantity of electroplating (current×time). Therefore, by controlling the electroplating using the current values, an electrodeposition state of metal can be understood regardless of concentration of metal ions in electrolyte solution.

In the manufacturing method of the substrate, it is effective that the pulse plating is performed in the fourth step in which the second metal material is deposited.

As described in the above, in the fourth step, the through-hole becomes the hole with the bottom by sealing the first opening part with the first metal material. The electrolyte solution is hard to pass in or out of the hole with the bottom, which leads to intensively deposit metal at the deposited metal portion projecting convexly toward the electrolyte solution; thereby exhausting the metal ions in the hole. As shown in the configuration, by performing the pulse plating in the fourth step, it is possible to suppress the lowering of the concentration of the metal ions in the electrolyte solution with flattening a convex. Further, after flattening the convex, it is possible to suppress local adhesion of the metal ions to the sidewall of the hole and deposit the second metal material in the hole by performing the pulse plating.

The manufacturing method of the substrate is effectively applicable to the substrate where a plurality of the through-holes is formed and variations in distribution of the through-holes appear. Also, the manufacturing method of the substrate is effectively applicable to the substrate where a plurality of the through-holes is formed and the through-holes have more than one kind of diameters or shapes.

In the case of the substrate where a plurality of the through-holes are formed, when the through-hole exists in the area where the through-holes are formed densely or the electrolyte solution is hard to pass in or out of the hole due to the shape of the through-hole, the concentration of the metal ions of the electrolyte solution in the hole tends to decrease during the electroplating. On the other hand, with respect to the through-hole formed in the area where the through-holes are formed sparsely and the through-hole where the electrolyte solution is relatively easy to go into inside thereof, the concentration of the metal ions in the hole is hard to decrease during the electroplating. That is, due to the factor of formation state of the through-holes and so on, concentrations of metal ions in the plating bath result in making a difference. Between the area where the concentration of metal ions is high and the area where the concentration of metal ions is low, a difference in current density of the electrodeposition arises, which leads to the variations in the degree of the growth in plating. According to the configuration, by performing the pulse plating, the concentrations of metal ions in the plating bath are hard to make a difference; thereby equalizing the state of filling in the through-hole.

In the manufacturing method of the substrate, in the first step, it is preferable that the glass substrate having the through-hole whose shape at a cross section is a flared shape at the first opening part side is prepared.

According to the configuration, the primary plating layer is easy to be formed on near the first opening part of the sidewall of the through-hole since the first opening part spreads toward the first surface of the substrate in which the primary plating layer is to be formed.

In the manufacturing method of the substrate, it is preferable that the first metal material and the second metal material are the same metal material.

According to the configuration, the third step where the first opening part is sealed with the metal and the fourth step where the through-hole is filled with metal can be continuously performed in the same plating bath. Also, when the first metal material and the second metal material are the same metal material, an electrical interface fails to arise between an electrodeposited portion by the plating in the third step and an electrodeposited portion by the plating in the fourth step. The substrate having good high frequency property can be obtained since the first metal material and the second metal material are composed of the same metal material.

The metal material used in the manufacturing method of the substrate is preferably the metal having a low electric resistance, is preferably, for example, a metal constituted by one or an alloy constituted by two or more selected from copper, nickel, gold, silver, platinum, palladium, chromium, aluminum and rhodium.

According to the configuration, conduction through the front and rear surfaces of the glass substrate is surely ensured since the above metal materials is filled in the through-hole. Therefore, the glass substrate can be preferably applicable to use of substrate mounted with electronic components such as a wiring substrate.

In the specification, disclosed is also a manufacturing method of a wiring substrate. In the manufacturing method of the wiring substrate, after manufacturing the glass substrate with the through-hole filled with the metal by the above manufacturing method of the substrate, a wiring pattern is formed on at least one of the first surface and the second surface of the glass substrate.

According to the configuration, it is possible to shorten the time of filling the above through-hole; thereby efficiently manufacturing the wiring substrate using the glass substrate as a core substrate. Also, when configuring a double-sided wiring substrate, the front and rear surfaces of the wiring substrate can be metalized by inexpensive plating. Further, by constituting the first metal material, the second metal material and a wiring with the above metals, all of the wiring circuits can be composed of the low electrical resistance materials.

According to the present invention, compared with the conventional method, it is possible to shorten the time of finishing filling the through-hole with metal by the electroplating. Thus productivity of the substrates composed of the glass substrate with the through-hole filled with metal, can be improved.

Also, according to the present invention, when filling with the metal the through-hole formed on the glass substrate, generation of the void in the through-hole can be prevented from occurring; thereby achieving the wiring substrate enabling a high-density mounting with high connection reliability for electronic components and so on.

Also, according to the present invention, when filling with metal the plurality of the through-holes formed on the glass substrate, it is possible to avoid the variations in the degree of filling with metal in each through-hole without the decrease in productivity resulting from making processes more complicated and so on.

### BRIEF DESCRIPTION OF THE DRAWINGS

FIG. 1 is a cross sectional view showing a configuration example of a wiring substrate according to first to third embodiments of the present invention.

FIGS. 2A and 2B are process drawings to explain a manufacturing method of a wiring substrate according to first to third embodiments of the present invention (part 1).

FIGS. 3A to 3C are process drawings to explain a manufacturing method of a wiring substrate according to first and third embodiments of the present invention.

FIG. 4 is an enlarged view showing a cross sectional shape of a through-hole according to first to third embodiments of the present invention.

FIGS. 5A to 5C are process drawings to explain a manufacturing method of a wiring substrate according to first to third embodiments of the present invention (part 2).

FIGS. 6A to 6C are process drawings to explain a manufacturing method of a wiring substrate according to first to third embodiments of the present invention (part 3).

FIG. 7 is a flow chart to explain a manufacturing method of a wiring substrate according to a first embodiment of the present invention.

FIGS. 8A to 8D are process drawings to explain a manufacturing method of a wiring substrate according to a second embodiment of the present invention.

FIG. 9 is a timing diagram to explain a pulse reverse plating method according to second and third embodiments of the present invention.

FIG. 10 is a flow chart to explain a manufacturing method of a wiring substrate according to a second embodiment and a third embodiment of the present invention.

FIG. 11 is a plain view showing a placement example of a through-hole on a glass substrate constituting a wiring substrate according to a third embodiment of the present invention.

FIGS. 12A and 12B are process drawings to explain a manufacturing method of a wiring substrate according to a third embodiment of the present invention.

FIGS. 13A to 13D are process drawings to explain a conventional manufacturing method of a wiring substrate.

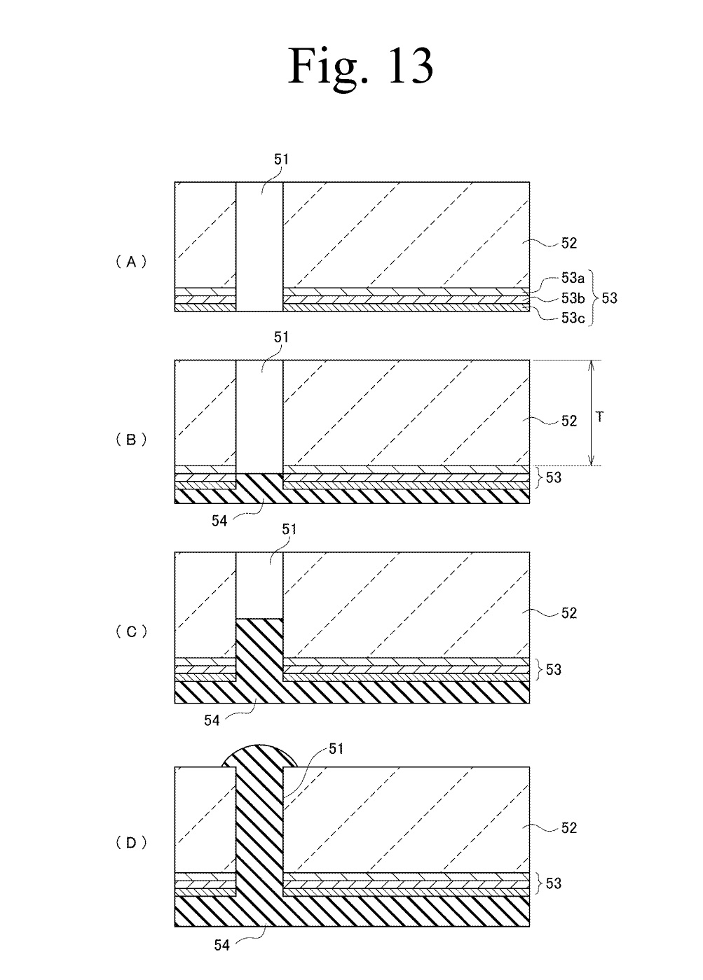

### DETAILED DESCRIPTION OF THE INVENTION

First, characteristics of some embodiments described in the specification are organized as follows:

(Characteristic 1) As for a glass substrate, a substrate constituted by a photosensitive glass is prepared. The photosensitive glass substrate is suitable for a substrate material of wiring glass substrate since a through-hole may be high-precisely formed on the photosensitive glass substrate.

(Characteristic 2) As for the photosensitive glass substrate, the photosensitive glass substrate pretreated for suppression of ion migration is prepared. The photosensitive glass substrate contains alkali metal ions such as a lithium ion and a potassium ion. Alkali metal ions in the substrate are fixed by irradiation of ultraviolet rays and heat treatment. Ion migration is suppressed since movement of alkali metal ions is suppressed.

(Characteristic 3) The glass substrate where surface roughening process is conducted on at least sidewall of the through-hole is prepared. Adhesion between metal filled in the through-hole and the wall surface of the through-hole is improved by conducting surface roughening process on the inside of walls of the through-hole.

(Characteristic 4) A primary plating layer is formed by sputtering method. By the sputtering method, metal layers are adhesively formed on the glass substrate.

(Characteristic 5) The primary plating layer has a two-layer structure and a first layer formed on the glass substrate is a chromium layer. The chromium layer is adhesively formed on the glass substrate. Gas barrier property between metal filled in the through-hole and sidewall of the through-hole is particularly improved by forming the chromium layer with good adhesion.

(Characteristic 6) Current density of plating in a metal filling step is lower than current density of plating in an opening part sealing step. Growth in plating in the metal filling step is preferably slow in order to fill with metal further densely. Dense film can be formed by suppressing current density of plating. Also, when electrolysis voltage rises in the metal filling step, there is fear of generation of gas (for example, hydrogen) by other electrolytic reaction. The other electrolytic reaction is prevented by lowering electrolysis current.

(Characteristic 7) After the metal filling step and before a substrate planarization stage, a first surface of the glass substrate is exposed by removing the first metal material and the primary plating layer from the first layer of the glass substrate. The first surface and second surface of the glass substrate are the exposed surface constituted by common material (glass). Therefore, planarization treatment can be conducted on both surfaces at the same time.

### First Embodiment

### <1. Outline of a Constitution of a Wiring Substrate>

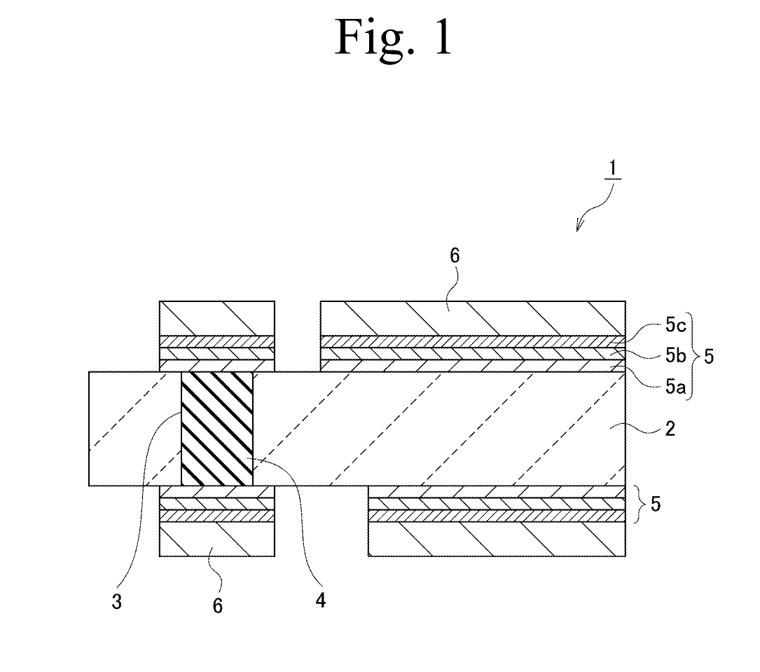

FIG. 1 is a cross sectional view showing a configuration example of a wiring substrate according to an embodiment of the present invention. The wiring substrate 1 shown in FIG. 1 is constituted by the glass substrate 2. The glass substrate 2 is used as a core substrate of the wiring substrate 1. A plurality of through-holes (only one through-hole is shown in FIG. 1) are provided on the glass substrate 2. Metal 4 is filled in the through-hole 3. A wiring pattern 6 is formed via an adhesive layer 5 on a first surface and a second surface of the glass substrate, respectively. Therefore, the wiring substrate constitutes a double-sided wiring substrate. The first surface and the second surface of the glass substrate have a relation of a front surface and a rear surface each other. In FIG. 1, a lower surface of the glass substrate is considered as the first surface and an upper surface is considered as the second surface. The wiring pattern 6 is formed as a pattern shape depending on wiring route.

The glass substrate 2 is constituted by a photosensitive glass substrate. The photosensitive glass substrate used as the glass substrate 2 has good properties such as smoothness, hardness, insulation and workability; thus being suitable for a core substrate of the wiring substrate 1. Other than the photosensitive glass substrate, such chemical strengthened glass as soda-lime glass, alkali free glass and aluminosilicate glass and so on have these properties. These glasses may be used as the core substrate of the wiring substrate 1.

The through-hole 3 is formed as a round shape in planar view. When working the present invention, placement of the through-holes 3 is not limited. Therefore, for example, the through-holes 3 may be placed at random in response to pattern shape of the desired wiring pattern 6, may be placed at a matrix with a predetermined gap, and may be placed at arrays other than matrix shape.

Also, in FIG. 1, metal 4 electrically connects wiring patterns 6 formed on both surfaces (the first surface and the second surface) of the glass substrate 2 each other, as previously explained. Therefore, metal 4 is preferably metal material (conductive material) which has a low resistance. Also, in the present embodiment, electroplating is used as a means of filling the through-hole 3 with metal 4. Therefore, metal 4 is preferably a metal material suitable for electroplating.

Specifically, metal 4 is composed of a metal constituted by one or an alloy constituted by two or more selected from copper, nickel, gold, silver, platinum, palladium, chromium, aluminum and rhodium. In the present embodiment, metal 4 is constituted by copper.

An adhesion layer 5 is the layer to reinforce adhesion of the wiring pattern 6 to the glass substrate 2. The adhesion layer 5 has the same pattern shape as that of the wiring pattern 6. In the present embodiment, copper constitutes the wiring pattern 6 as well as metal 4. When copper is directly stacked on the glass substrate 2, sufficient adhesion cannot be obtained. Therefore, the adhesion layer 5 intermediates between the glass substrate 2 and the wiring pattern 6. The adhesion layer 5 may have a two-layer structure including a chromium layer and a copper layer, have a three-layer structure where a chromium-copper layer intermediates between these layers, and have a multilayer structure having four layers or more. In the present embodiment, as an example, the adhesion layer 5 has the three-layer structure. Specifically, the adhesion layer 5 has the three-layer structure where the chromium layer 5a, the chromium-copper layer 5b and the copper layer 5c are stacked in sequence on the glass substrate 2.

The wiring pattern 6 is stacked on the adhesion layer 5. More specifically, the wiring pattern 6 is formed on the copper layer 5c which is outermost layer of the adhesion layer 5. A part of the wiring pattern 6 formed on the first surface of the glass substrate 2 and a part of the wiring pattern 6 formed on the second surface of the glass substrate 2 are electrically connected (conducted) via metal 4 filled in the through-hole 3.

### <2. Procedure of the Manufacturing Method of the Wiring Substrate>

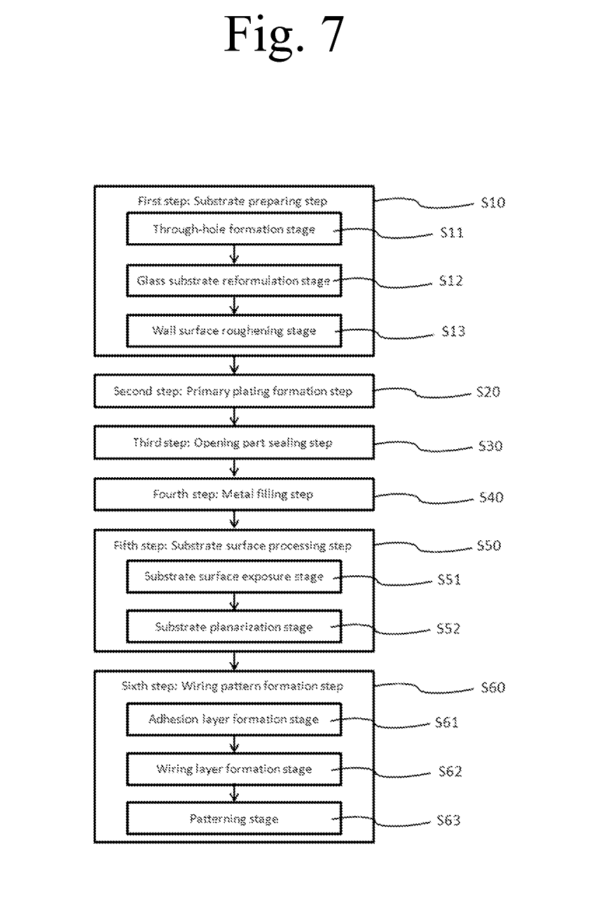

Next, the manufacturing method of the wiring substrate according to the present embodiment will be explained referring to a flow chart of FIG. 7.

The manufacturing method of the wiring substrate according to the present embodiment includes a substrate preparing step (S10); a primary plating layer formation step (S20); an opening part sealing step (S30) in which one opening part of the through-hole formed on the substrate is sealed; a metal filling step (S40) in which the hole is filled with metal; a substrate surface processing step (S50) in which the surface of the substrate is processed; and a wiring pattern formation (S60) in which the wiring pattern is formed on the surfaces of the substrate. Each step is explained in sequence.

### (First Step: Substrate Preparing Step S10)

The substrate preparing step S10 includes a the through-hole formation stage S11 in which the through-hole 3 is formed on the glass substrate 2, a glass substrate reformulation stage S12 in which the properties of the glass substrate 2 are stabilized, and a wall surface roughening stage S13 in which adhesion between a sidewall of the through-hole 3 of the substrate 2 and metal 4 is improved.

### (Through-hole Formation Stage S11)

The through-hole formation stage S11 is the process in which the through-hole 3 is formed on the glass substrate 2. The through-hole formation stage S11 corresponds to the process in which on the plate glass base material having the first surface and the second surface which have a relation of a front surface and a rear surface, the through-hole whose one opening part at the first surface side is determined as a first opening part and whose the other opening part at the second surface side is determined as a second opening part, is formed. Therefore, as for the means of obtaining the glass substrate 2 with the through-holes 3 except for performing the through-hole formation stage S11, for example, the glass substrate 2 with through-holes 3 may be purchased from other makers. As for the method of forming the through-hole, for example, a laser machining method and a photolithography method may be used. In the present embodiment, the photolithography method is used in view of precise formation of the through-holes 3, compared to the laser machining method. The photolithography method is conducted by an exposure treatment and a development treatment. Therefore, as for the glass base material for forming the through-hole 3, a photosensitive glass in which photosensitive substances are diffused in the glass is used.

In that case, the photosensitive glass substrate 2 is not particularly limited, and any substance may be used as long as it shows photosensitivity. The glass substrate 2 preferably contains as a photosensitive component at least one of gold (Au), silver (Ag), cuprous oxide (Cu₂O) or cerium oxide (CeO₂), more preferably contains two or more components. As for such glass substrate 2, for example, a glass substrate containing, in terms of mass %, 55 to 85% of SiO₂; 2 to 20% of aluminum oxide (Al₂O₃); 5 to 15% of lithium oxide (Li₂O), and SiO₂+Al₂O₃+Li₂O>85% as a basic component; 0.001 to 0.05% of Au, 0.001 to 0.5% of Ag, and 0.001 to 1% of Cu₂O as a photosensitive metal component; and 0.001 to 0.2% of CeO₂ as a photosensitizer can be used.

Hereinafter, specific procedure in which the through-hole 3 is formed on the glass substrate 2 by photolithography method will be explained. First, a potion for forming the through-hole 3 on the glass substrate 2 (hereinafter referred to as “through-hole formation portion” is exposed. In this exposing treatment, photomask having an mask opening (not shown in FIGS.) is used. The photomask is used for, for example, forming a light blocking film (chromium film and so on) in desired pattern shape on the transparent and thin glass substrate, and blocking pass of exposing light (ultraviolet rays in the present embodiment) by this light blocking film. In the above exposing treatment, this photomask is placed closely on the first surface or the second surface of the glass substrate 2. Next, the ultraviolet ray is irradiated to the glass substrate 2 via photomask. Thus, the ultraviolet is irradiated to the glass substrate 2 through the mask openings formed on the photomask corresponding to the through-hole formation portion of the glass substrate 2.

Next, the glass substrate 2 is subjected to thermal treatment. The thermal treatment is preferably performed at a temperature between the transition point and deformation point of the photosensitive glass substrate. This is because at temperatures lower than the transition point, thermal treatment effects are not sufficiently obtained, and at temperatures exceeding the deformation point, shrinkage of the photosensitive glass substrate 2 occurs, which may cause lowering of the exposure dimension accuracy. The thermal treatment is preferably performed for about 30 minutes to 5 hours.

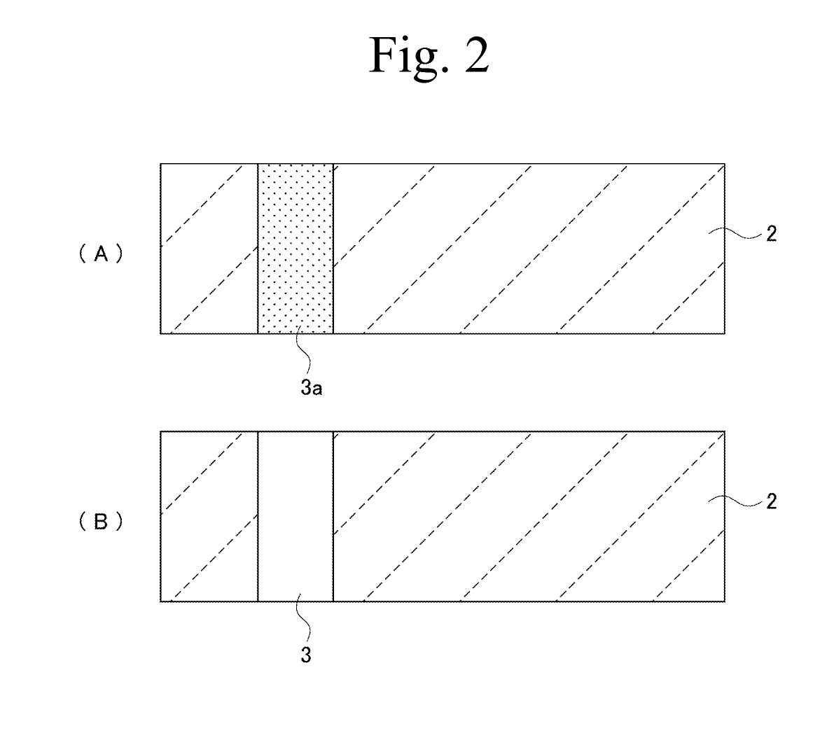

By such ultraviolet irradiation and heat treatment, the through-hole formation portion irradiated with the ultraviolet rays is crystallized. As a result, exposure crystallization potion 3a is formed on the through-hole formation portion of the glass substrate 2, as shown in FIG. 2A.

Subsequently, the above glass substrate 2 on which the exposure crystallization potion 3a is formed is developed. In the developing treatment, as developing fluid, an etching solution such as diluted hydrofluoric acid with moderate concentration is sprayed or so to the glass substrate 2. By this developing treatment, the exposure crystallization potion 3a is selectively dissolved and removed. As a result, the through-hole 3 is formed on the glass substrate 2 as shown in FIG. 2B. This through-hole has an opening part at a lower surface (the first surface) and an opening part at an upper surface (the second surface) respectively on the glass substrate 2. Hereinafter, the opening part of the through-hole opening into the lower surface of the glass substrate 2 (the first opening part) is considered as a lower opening part, and the opening part of the through-hole opening into the upper surface of the glass substrate 2 (the second opening part) is considered as an upper opening part.

According to the above forming method of the through-hole 3 using the photolithography method, just a desired number of the through-holes 3 with an aspect ratio of about 10 can be simultaneously formed on the glass substrate 2. For example, in the case of using the glass substrate 2 having a thickness of about 0.3 to 1.5 mm, a plurality of the through-holes 3 with a diameter of about 30 to 150 μm can be formed simultaneously at desired locations. Thus, formation of fine wiring patterns and improvement of efficiency in the through-hole formation step can be attained. Further, in the case of employing a landless structure in which the land width is reduced to a very small value or zero in order to increase the density of wiring patterns, a sufficiently large space between the through-holes 3 can be secured. As a result, wirings can be formed also in the space between the through-holes 3, so that the degree of freedom in wiring pattern design can be expanded as well as the wiring density can be increased. Further, a plurality of the through-holes 3 can be formed at a narrow pitch; thereby increasing the wiring density.

### (Glass Substrate Reformulation Stage S12)

As stated above, after forming the through-hole 3 by using the photosensitive glass substrate 2, a glass substrate reformulation stage S12 is performed if needed. Hereinafter, the glass substrate reformulation stage S12 will be explained.

The photosensitive glass substrate 2 usually contains alkali metal ions such as a lithium ion (Li⁺) and a potassium ion (K⁺). When these alkali metal ions leak from the substrate 2 to a wiring metal of the wiring substrate 1 and water is absorbed to the wiring metal; thus causing an ion migration that the wiring metal is ionized between circuits to which a voltage is applied and that the ionized wiring metal is reduced by receiving a charge again, which leads to allow the metal to be deposited. Due to the ion migration, in the worst case, another wiring from one circuit to another circuit is formed by the deposited metal; as a result, a short circuit may occur between circuits. Such a short circuit defect becomes remarkable when a gap between wirings is small. Therefore, in order to form fine wirings with high density, the ion migration must be inhibited.

In the glass substrate reformulation stage S12, the whole glass substrate 2 with the through-hole 3 formed, is irradiated, for example, with ultraviolet rays in an exposure amount of about 700 mJ/cm², and then subjected to thermal treatment at a temperature of about 850° C. for about two hours; Thus, the glass substrate 2 is crystallized. Due to the crystallization of the whole photosensitive glass substrate 2 in this way, alkali ions included in the glass substrate 2 are hard to move therein after the crystallization, compared to before the crystallization. Therefore, the ion migration can be inhibited.

### (Wall Surface Roughening Stage S13)

After crystallizing the glass substrate 2 in the glass substrate reformulation stage S12, a wall surface roughening stage S13 is performed.

The wall surface roughening stage S13 is the process in which at least a surface of sidewall of the through-hole 3 formed on the glass substrate 2 is roughened. Roughening surface is the treatment in which the surface is turned into roughened surface; more specifically, surface treatment is performed to cause a change of the surface roughness so that the difference of the surface roughness before and after the roughening treatment can be distinguished by SEM (Scanning Electron Microscope) observation. Note that, in the wall surface roughening stage S13, at least sidewall surface of the through-hole 3 is roughened; the front and rear surfaces of the glass substrate and side edge surface of the glass substrate may be roughened, other than the sidewall surface.

The surface roughening is performed as follows: In the present embodiment, to the glass substrate 2 with the through-hole 3 formed and crystallized, an etching treatment is conducted using an etching solution consisting of a mixture of acid ammonium fluoride (NH₄F.HF) and ammonium sulfate ((NH₄)₂SO₄) in a predetermined ratio. By doing such etching treatment, among a variety of materials constituting the glass substrate 2, materials which can dissolve easily in the above etching solution (for example, quartz glass composed of SiO₂) is selectively and preferentially dissolved and removed. As a result, on the etched surface (including the sidewall surface of the through-hole 3), a lot of fine etched scratches are formed. By forming these etched scratches, the surface of glass substrate 2 is roughened.

With respect to thus roughened surface, wettability of the metal materials filled in the through-hole 3 in the after-mentioned fourth step (metal filling step S40) is improved compared to the surface which is not roughened. Also, after filling the hole with the metal materials, the metal materials can penetrate into the bottom of the etched scratches formed by the surface roughening; thereby an anchor effect is produced. Therefore, adhesion strength of the metal materials to the roughened surface is enhanced compared to the surface which is not roughened.

Note that, the surface roughening in the wall surface roughening stage S13 is not always necessary to be achieved by the aforementioned etching treatment, for example, may be achieved by other procedures such as machinery grinding process.

### (Second Step: Primary Plating Layer Formation Step S20)

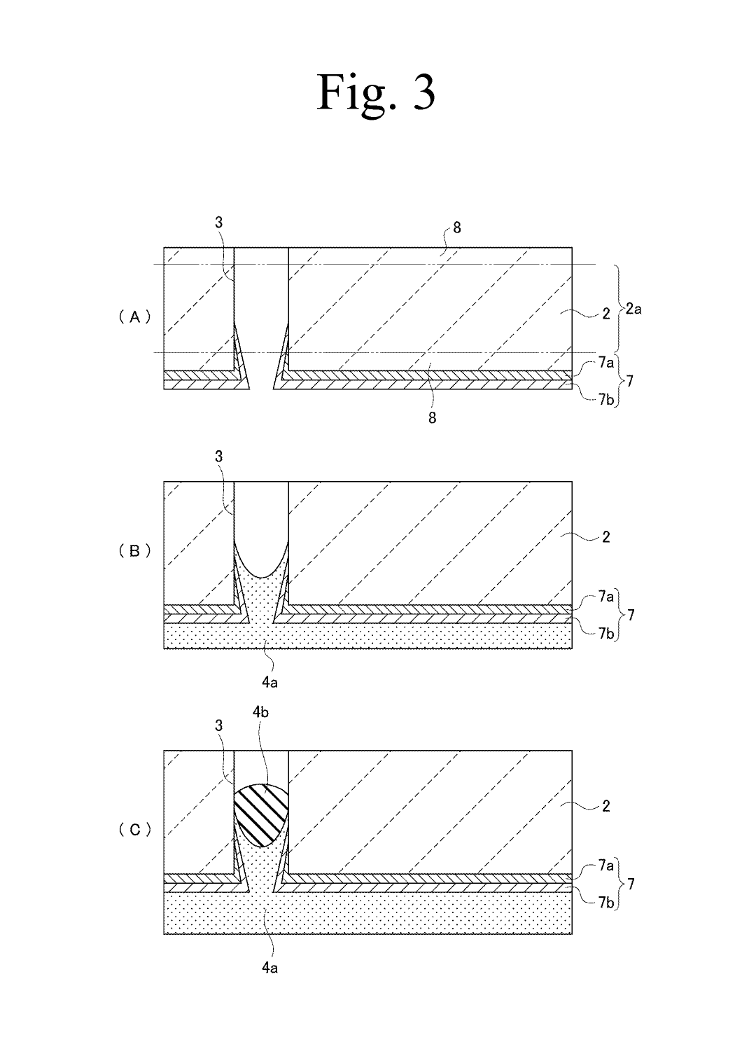

The primary plating layer formation step S20 is the process in which a primary plating layer 7 made of metal is formed on the lower surface side of the glass substrate 2. In the step, the primary plating layer 7 is formed on only the lower surface side of the glass substrate 2, not on the upper surface side of the glass substrate 2. Also, in the primary plating layer formation step S20, as shown in FIG. 3A, the primary plating layer is formed on from the edge of the lower opening part (the first opening part) of the through-hole 3 to a part of the sidewall surface of the through-hole 3 as well as the lower surface of the glass substrate 2. Due to this, while a portion of the sidewall of the through-hole 3 located at the lower surface side of the glass substrate 2 is covered with the primary plating layer 7, a portion of the sidewall of the through-hole 3 located on the upper surface side of the glass substrate 2 is exposed without covered with the primary plating layer 7. Incidentally, “a part of the sidewall surface of the through-hole” described here is considered as the sidewall portion where an area occupies a part of the through-hole 3 in depth direction and the sidewall portion where an area continues from the edge of the lower opening part of the through-hole 3 to a back side of the through-hole 3 (the upper opening part).

In the depth direction of the through-hole 3, an area for forming the primary plating layer is preferable to be ensured at positions located on backward of the through-hole 3 beyond an area to be removed 8 of the glass substrate 2. The area to be removed 8 of the glass substrate 2 is the area which is supposed to be removed from the glass substrate 2 when removing the surface part of the glass substrate 2 by machinery processing in the after-mentioned fifth step (substrate surface processing step S50). In FIG. 3A, the surface of the glass substrate 2 is supposed to be removed by machinery processing to the positions shown by two two-dot chain lines. Therefore, after finishing the machinery processing for the glass substrate 2, a substrate part 2a between the two two-dot chain lines remains as the glass substrate 2 finally.

The areas to be removed 8 of the glass substrate 2 are set to both sides of the glass substrate 2, respectively. Between them, with respect to the area to be removed 8 of the glass substrate 2 set to the lower surface side of the glass substrate 2, the primary plating layer 7 is formed thereon so that the lower opening part of the through-hole 3 remains sealed by the primary plating layer 7 and a first plating layer 4a (described below) even after removing the surface of the glass substrate 2 by machinery processing. Specifically, the primary plating layer 7 is formed at the backward of the through-hole 3 beyond the boundary position (the position shown by the two-dot chain line) of the area to be removed 8.

The primary plating layer 7 is preferably formed by sputtering which causes good adhesion with the glass substrate 2. Specifically, on the lower surface side of the glass substrate 2, for example, the primary plating layer 7 which has two-layer structure is formed by stacking chromium layer 7a whose thickness is about 0.05 μm and copper layer 7b whose thickness is about 1.5 μm in sequence using the sputtering. In doing so, a part of scattered metal atoms from a target (hereinafter referred to as “sputtering atoms”) goes into the through-hole 3 from the lower opening part of the through-hole 3 and adheres to the sidewall of the through-hole 3. For this reason, in order to make the sputtering atoms effectively adhere to the sidewall of the through-hole 3, in the above through-hole formation stage S11, it is preferable to form the through-hole 3 on the glass substrate 2 so that a cross sectional shape of the through-hole 3 at the lower opening part side becomes flared shape.

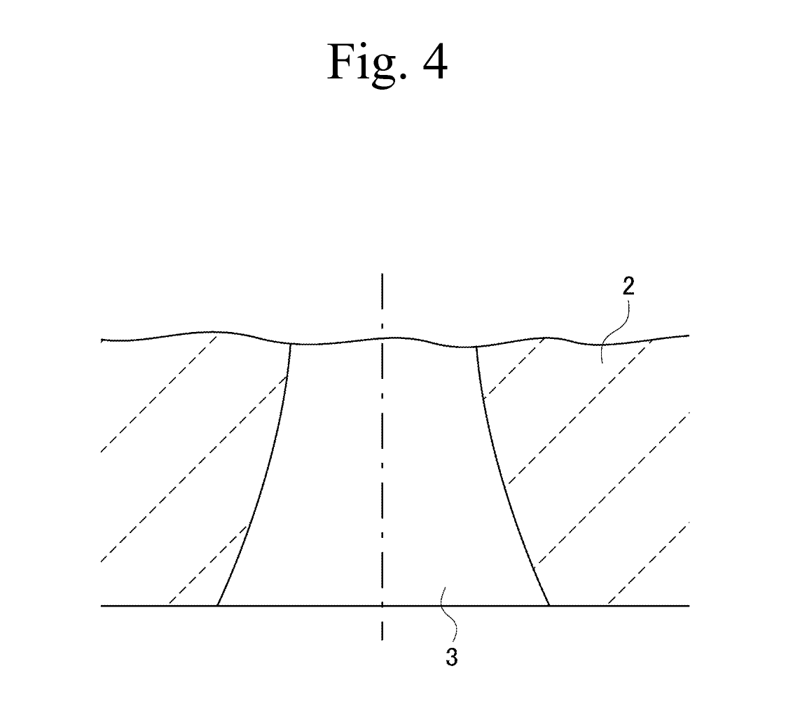

Specifically, in the above through-hole formation stage S11, when dissolving the exposure crystallization potion 3a by the etching solution, it is controlled that a portion near the edge of the lower opening part of the glass substrate 2 is made to be more soluble by adjusting concentration of the etching solution accordingly in the depth direction of the through-hole 3, compared with a portion far the edge of the lower opening part. Due to this, the through-hole 3 is formed so that a diameter of the through-hole 3 becomes larger gradually from the center toward the upper and the lower opening parts in the depth direction. By forming the through-hole 3 in this way, when sputtering the above chromium layer 7a and copper layer 7b, the sidewall of the through-hole 3 at the lower opening part side broadens to the central axis of the through-hole 3 (shown by chain line) as shown in FIG. 4. Therefore, the sputtering atoms which go into the through-hole 3 from the lower opening part of the through-hole 3 by the sputtering become easier to adhere to the sidewall surface of the through-hole 3. Formation range of the primary plating layer 7 in the depth direction of the through-hole 3 is, for example, preferably at least a one-twentieth or more, more preferably a one-tenth or more, further preferably about a one-fifth to a half of the depth of the through-hole 3 (thickness of the glass substrate 2). The sidewall surface of the through-hole 3 may be coated with the primary plating layer 7 in the above range.

### [Third Step: Opening Part Sealing Step S30]

An opening part sealing step S30 is the step in which the lower opening part is sealed with the first plating layer 4a by forming the first plating layer which is the layer of the first metal material using electroplating on the lower side of the glass substrate 2. In this step S30, as shown in FIG. 3B, the lower opening part of the through-hole 3 is sealed with the first plating layer 4a by making the first layer 4a grow from the surface of the primary plating layer 7 not only on the lower surface of the glass substrate 2 but also the inside of the through-hole 3. In the present embodiment, the first plating layer 4a is formed by the electrolytic copper plating. That is, in the present embodiment, copper is used as the first metal material.

In the electroplating of the opening part sealing step S30, for example, in a plating bath containing an aqueous solution of a copper sulfate as a plating solution, a copper plate as an anode and the primary plating layer 7 of the glass substrate 2 as a cathode are arrayed respectively. In so doing, the lower surface side of the glass substrate 2 is faced toward the anode (copper plate) in order to conduct the electroplating from the lower surface side (the first surface side) of the glass substrate 2 on which the primary plating layer 7 is formed. Then, the anode and the cathode are connected with DC power supply and by applying a predetermined voltage range, for example, voltage ranges of 1 to 5 V when acid bath is employed as plating bath; thereby depositing copper on the surface of the primary plating layer 7. Note that, it is necessary that the applied voltage is set within the range where other electrolytic reaction fails to occur in the reaction system in the plating bath, for example, the range in which the applied voltage fails to reach a hydrogen overvoltage at the anode.

Depending on a diameter of the through-hole 3, the formation of the first plating layer 4a is performed, for example, under the conditions that current density is, for example, 1 A/dm² to 5 A/dm². Further, this current density also depends on a pH of the plating bath or ion concentration of copper, therefore, a value of the current density is set to an appropriate value. Generally, in the case where the ion concentration of copper is high, the current density can be set higher compared to a case where the ion concentration of copper is low. By performing the electroplating under these current density conditions, the lower opening part of the through-hole 3 can be sealed with the first plating layer 4a. In this case, a part of the first plating layer 4a stacked on the primary plating layer 7 by the electroplating grows toward the backward of the through-hole 3 beyond the primary plating layer 7 as if crawling up the sidewall surface of the through-hole 3. Also, a surface of the first plating layer 4a inside the through-hole 3 becomes hollow with nearly a U-shaped or a V-shaped cross sectional shape in the center of the through-hole 3.

### [Fourth Step: Metal Filling Step S40]

A metal filling step S40 is the step in which the through-hole 3 is filled with metal by depositing the second plating layer 4b which is the layer of the second metal material inside the through-hole 3 using the electroplating from the upper surface side of the glass substrate 2. “The electroplating from the upper surface side of the glass substrate 2” described here shows the electroplating which is conducted by placing the anode so as to face the upper surface side of the glass substrate 2 among the upper surface and the lower surface of the glass substrate 2. Also, “The through-hole 3 is filled with metal” shows the filling of a portion which is not embedded with the first plating layer 4a inside the through-hole 3 (non-filling portion) with the second metal material, when the lower opening part of the through-hole 3 is sealed with the first plating layer 4a in the aforementioned opening part sealing step S30.

In the metal filling step S40, as shown in FIG. 3C, the through-hole 3 is filled with metal by growing the second plating layer 4b from the surface of the first plating layer 4a toward the upper opening part of the through-hole 3 inside the through-hole 3. In the present embodiment, the second plating layer 4b is formed in the through-hole 3 by copper electroplating as well as the aforementioned first plating layer 4a. In this case, inside the through-hole 3, the chromium and the copper which constitute primary plating layer (chromium layer 7a and copper layer 7b) exists as well as the copper constitutes the first plating layer 4a and the second plating layer 4b; thereby the through-hole 3 becomes filled with these metals.

As described in the above, in the primary plating layer formation step S20, primary plating layer 7 is formed on from the edge of the lower opening part to the part of sidewall surface of the through-hole 3. For this reason, in the opening part sealing step S30, the first plating layer 4a grows from the surface of the primary plating layer 7 inside the through-hole 3. Due to this, the first plating layer 4 starts growing from the position which is the backward of the through-hole 3 beyond the lower opening part of the through-hole 3. In the growth process, the first plating layer 4a seals the lower opening part of the through-hole 3. Then, when the lower opening part of the through-hole 3 is sealed with the first plating layer 4a, a part of the through-hole 3 is already filled with the first plating layer 4a. Therefore, in the metal filling step S40, when the second plating layer 4b is formed in the through-hole 3 by the electroplating from the upper surface side of the glass substrate 2, a depth dimension of the through-hole 3 to be filled by the growth of the second plating layer 4b becomes shorter than a total dimension of the through-hole 3. As a result, it is possible to shorten the time of finishing filling the through-hole with metal, compared with the conventional case of growing the plating layer through the total dimension of the through-hole 3.

When performing the electroplating in the metal filling step S40, for example, a copper plate as an anode and the first plating layer 4a of the glass substrate 2 as a cathode are placed respectively in the plating bath containing copper sulfate aqueous solution as a plating solution. In so doing, the upper surface side of the glass substrate 2 is faced to the anode (copper plate) in order to perform the electroplating from the upper surface side (the second surface side) of the glass substrate 2 on which the first plating layer 4a is not formed. Then, the anode and the cathode are connected with the DC power supply and applied with a voltage within the predetermined range; copper is deposited over the surface of the first plating layer 4a. Due to this, the through-hole 3 is filled with both the primary plating layer 7 and the first plating layer 4a which are already formed before in the through-hole 3 and the second plating layer 4b stacked on the first plating layer 4a. This electroplating is performed with the current density which is lower than that in the opening part sealing step S30 (for example, about 0.2 A/dm² to 0.8 A/dm²). Also, a pulse plating method described in after-mentioned second embodiment and third embodiment may be employed as this electroplating.

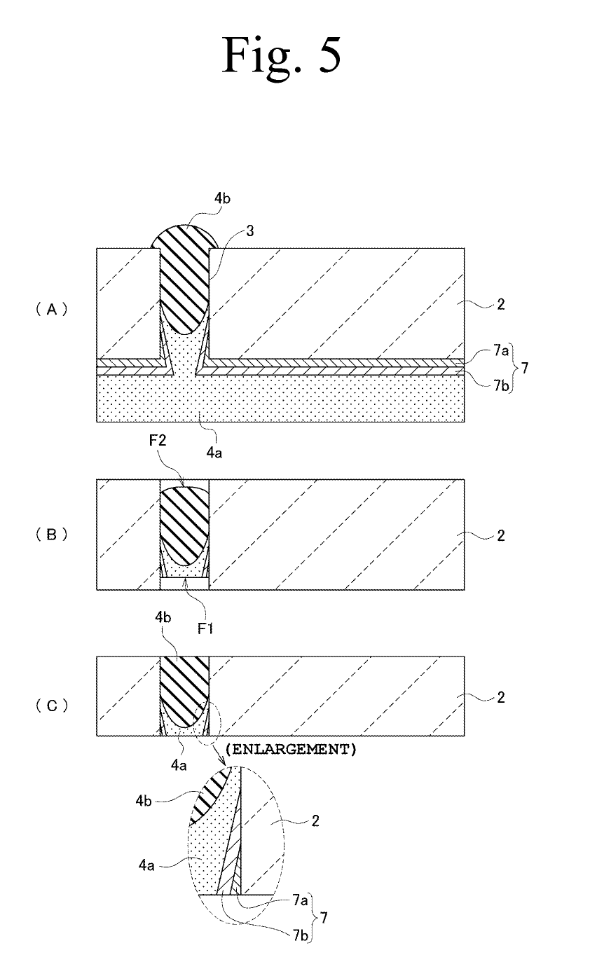

By performing the electroplating under such conditions, copper ions in the plating bath move from the upper opening part of the through-hole 3 into the inside of the through-hole 3 and are deposited over the surface of the first plating layer 4a. As a result, inside the through-hole 3, the through-hole 3 is gradually filled with the second plating layer 4b by making the second plating layer 4b grow from the surface of the first plating layer 4a which is already formed before toward the upper opening part. Then, when the surface of the second plating layer 4b reaches the upper opening part of the through-hole 3, the through-hole 3 becomes completely filled with the second plating layer 4b. Herein, in order to ensure the filling of the through-hole 3 by the growth of the second plating layer 4b, as shown in FIG. 5A, the electroplating continues until the surface of the second plating layer 4b is projected from the upper surface side of the glass substrate 2.

### [Fifth Step: Substrate Surface Processing Step S50]

The fifth step (substrate surface processing step S50) which is the next step of the metal filling step S40 includes a substrate surface exposure stage S51 in which unnecessary layer is removed from the glass substrate 2 with the through-hole 3 already filled with metal and a substrate planarization stage S52 where an exposed surface is planarized after removing.

### (Substrate Surface Exposure Stage S51)

The substrate surface exposure stage S51 is the process in which a lower surface of the glass substrate 2 is exposed by removing the first plating layer 4a and the primary plating layer 7 from the lower surface of the glass substrate 2. In this step, as shown by comparing FIG. 5A with FIG. 5B, not only the first plating layer 4a and the primary plating layer 7 which cover the lower surface of the glass substrate 2 are removed but also the second plating layer 4b which is projected toward the upper surface side of the glass substrate 2 is dented.

In the substrate surface exposure stage S51, an etching treatment is performed using a chemical solution suitable for constituent material of the film targeted for removal. In the present embodiment, an etching treatment is performed in twice with changing the chemical solution. First, in the first etching treatment, for example the copper constituting the first plating layer 4a and the copper constituting the copper layer 7b of the primary plating layer 7 are removed (dissolve) by the etching using, for example, the chemical solution whose main component is ferric chloride. Also, in the first etching treatment, the copper constituting the second plating layer 4b is removed by the etching. Next, in the second etching treatment, the chromium constituting the chromium layer 7a of the primary plating layer 7 is removed by the etching using, for example, the chemical solution whose main component is potassium ferricyanide.

Incidentally, in the first etching treatment, the copper is removed by the etching until the chromium layer 7b is exposed at the lower surface side of the glass substrate 2. However, inside the through-hole 3, an etching time and so on is adjusted so that a backdown surface Fl of the first plating layer 4a by the etching remains within the area 8 to be removed of the glass substrate 2 (referring to FIG. 3A). Also, at the upper surface side of the glass substrate 2, the surface of the second plating layer 4b is brought to be back in the through-hole 3 by the first etching treatment so that the surface of the second plating layer 4b is not projected from the upper surface of the glass substrate 2. Also in this case, the etching time and so on is adjusted so that a backdown surface F2 of the second plating layer 4b by the etching remains within the area 8 to be removed of the glass substrate 2 (referring to FIG. 3A).

### (Substrate Planarization Stage S52)

The substrate planarization stage S52 is the step in which at least the lower surface among the upper surface and the lower surface of the glass substrate 2 is planarized by machinery processing. In the present embodiment, both surfaces (the upper surface and the lower surface) of the glass substrate 2 are planarized by machinery processing. Specifically, the upper surface and the lower surface of the glass substrate 2 are planarized by both sides lapping, after that, the both sides of the glass substrate 2 are polished for finish if needed. By such machinery processing, each surface part at the upper surface side and the lower surface side of the glass substrate 2 is removed respectively in alignment with the boundary positions of the area to be removed 8 (the positions shown by the two-dot chain lines in FIG. 3A). As a result, as shown in FIG. 5C, both end surfaces of the metal filling the through-hole 3 are polished for finish so that the both end surfaces are flush with the upper surface and the lower surface of the glass substrate 2 respectively, as well as the both surfaces of the glass substrate 2 are planarized. Also, the lower opening part of the through-hole 3 of the glass substrate 2 is sealed by the primary plating layer 7 and the first plating layer 4a. In this case, inside the through-hole 3, the copper and the chromium constituting the primary plating layer 7 and the copper constituting the plating layers 4a and 4b remain. Then, the through-hole 3 is filled with these metals. In this way, the glass substrate 2 with the through-hole 3 filled with metal 4 is obtained as shown in the above FIG. 1.

As previously explained, in the primary plating layer formation step S20, the primary plating layer 7 is formed at the position of the backward of the through-hole 3 beyond the area to be removed 8 of the glass substrate 2. For this reason, in the above substrate planarization stage S52, the lower opening part of the through-hole 3 remains sealed with the primary plating layer 7 and the first plating layer 4a, even after removing the surface part of the lower surface of the glass substrate 2 by machinery processing. Under this situation, the first plating layer 4a stays strongly adhered to the sidewall surface of the through-hole 3 via the primary plating layer 7 by an effect of reinforcing adhesion brought by the primary plating layer 7. For this reason, the adhesion between the through-hole 3 and metal 4 becomes stronger compared with the case where manufacturing condition in which posterior to the substrate planarization stage the primary plating layer 7 fails to remain in the through-hole 3 is adopted. Therefore, airtightness (such as gas barrier property) in the through-hole 3 filled with metal 4 can be improved.

Further, prior to the substrate planarization stage S52, in the above substrate surface exposure stage S51, the first plating layer 4a and the primary plating layer 7 are removed from the lower surface of the glass substrate 2; the lower surface of the glass substrate 2 is exposed. Due to this, both the upper surface and the lower surface of the glass substrate 2 become exposed surfaces composed of the same (common) material “glass”. Because of this, in the substrate planarization stage S52, both sides lapping can be performed as a planarization processing of the glass substrate 2 by machinery processing. Thereby it becomes possible to planarize both sides of the glass substrate at the same time. Therefore, cost of manufacturing the substrate can be reduced, compared with the case where the planarization processing is performed to the surfaces of the glass substrate 2 one by one. Incidentally, when the upper surface and the lower surface of the glass substrate 2 are exposed surfaces composed of different materials each other, it becomes difficult to apply the both sides lapping; thus it is necessary to planarize the surface of the glass substrate one by one.

### [Sixth Step: Wiring Pattern Formation Step S60]

A wiring pattern formation step S60 is the step in which the wiring pattern is formed on at least one of the upper surface and the lower surface of the glass substrate 2. The wiring pattern formation step S60 includes an adhesion layer formation stage S61, a wiring layer formation stage S62 and a patterning stage S63. Hereinafter, each stage will be explained.

### (Adhesion Layer Formation Stage S61)

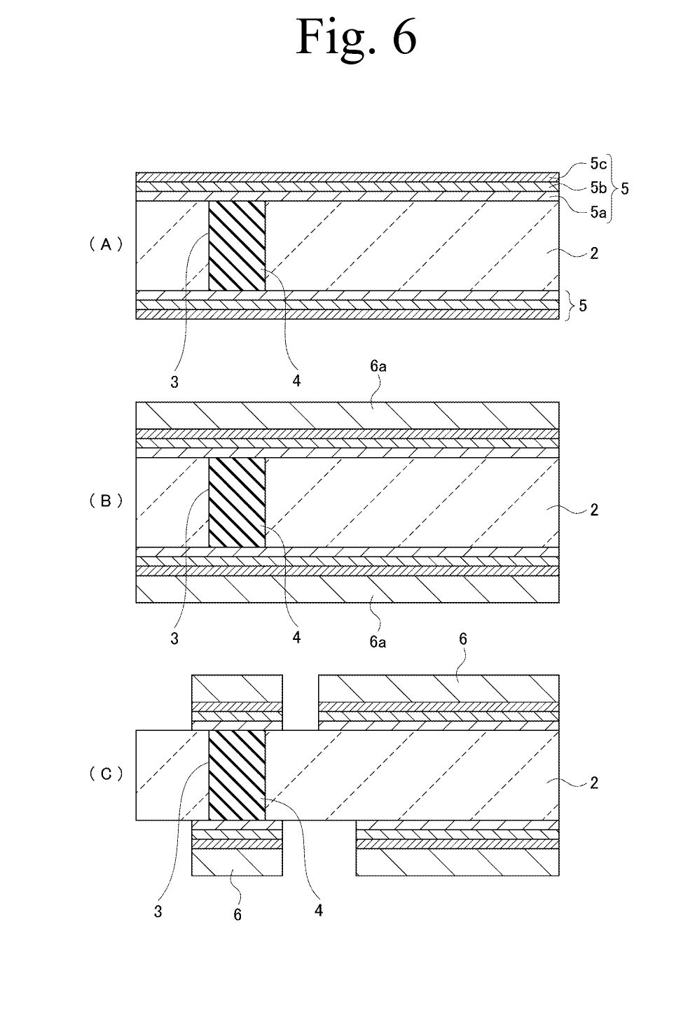

In the adhesion layer formation stage S61, as shown in FIG. 6A, the adhesion layer is formed on each surface of the glass substrate 2 by the sputtering method. In the present embodiment, the adhesion layer 5 is formed as the three-layer structure where the chromium layer 5a, the chromium-copper layer 5b and the copper layer 5c are stacked in sequence. It is preferable that each of the metal layers constituting the adhesion layer 5 is formed to be as thin as possible in view of an amount of side etching in the wiring pattern formation using an etching described later. However, if a thickness of each of the metal layers in the adhesion layer 5 is too thin, the adhesion layer 5 is likely to be removed by a treatment for patterning of the wiring layer. Therefore, for example, when the adhesion layer 5 is formed as the three-layer structure as previously described, it is preferable that the thickness of the chromium layer 5a is about 0.04 μm to 0.1 μm, the thickness of the chromium-copper layer 5b is about 0.04 μm to 0.1 μm and the thickness of the copper layer 5c is about 0.5 μm to 1.5 μm; thereby a total thickness of the adhesion layer 5 can be reduced to 2 μm or less.

### (Wiring Layer Formation Stage S62)

In the wiring layer formation stage S62, as shown in FIG. 6B, on each surface of the glass substrate 2, a wiring layer 6a is formed over the adhesion layer 5 formed before. The wiring layer 6a is formed by the electroplating. It is preferable that, in a similar way of the formation of the adhesion layer 5, this wiring layer 6a is formed to be as thin as possible in view of the amount of the side etching. However, in the case where the wiring layer 6a is too thin, when temperature changes of the glass substrate 2 are repeated due to the usage environment, metal fatigue may occur in the wiring pattern due to the deference in coefficient of thermal expansion between the wiring pattern 6a and the glass substrate 2. For this reason, in order to ensure connection reliability of the wiring pattern against the metal fatigue, the wiring layer 6a needs to have an adequate thickness. Specifically, the thickness of the wiring layer 6a is preferably about 1 μm to 20 μm, more preferably about 4 μm to 7 μm. When the thickness of the wiring layer 6a is less than 1 μm, it is highly possible that a break of the wiring may occur due to the above metal fatigue. Further, when the thickness of the wiring layer 6a is more than 20 μm, it becomes difficult to meet the demands for making the wiring pattern finer.

### (Patterning Stage S63)

In the patterning stage S63, as shown in FIG. 6C, on each surface of the glass substrate 2, the wiring pattern 6 is formed by patterning the adhesion layer 5 and the wiring layer 6a using the photolithography method and the etching. Specifically, after covering the wiring layer 6a of the glass substrate 2 with a resist layer which is not shown in figure, a resist pattern is formed by exposing and developing this resist layer; as a result, a part of the wiring layer 6a of the glass substrate 2 (a part to be remained as the wiring pattern) becomes covered with the resist pattern. Next, an exposed portion of the wiring layer 6a and the adhesion layer 5 is removed by the etching using the resist pattern as a mask. As a result, the wiring pattern 6 having the same pattern as the resist pattern is obtained. The resist used herein may be a liquid resist, a dry film resist or an electrodeposited resist. Also, the resist type may be either positive or negative. Generally, the positive resist has a higher resolution compared with the negative resist; therefore, the positive resist is suitable for forming a fine wiring pattern compared with the negative resist.

From the above, the substrate is manufactured through the first to fifth steps and the wiring substrate is manufactured by using the substrate through the sixth step.

### Second Embodiment

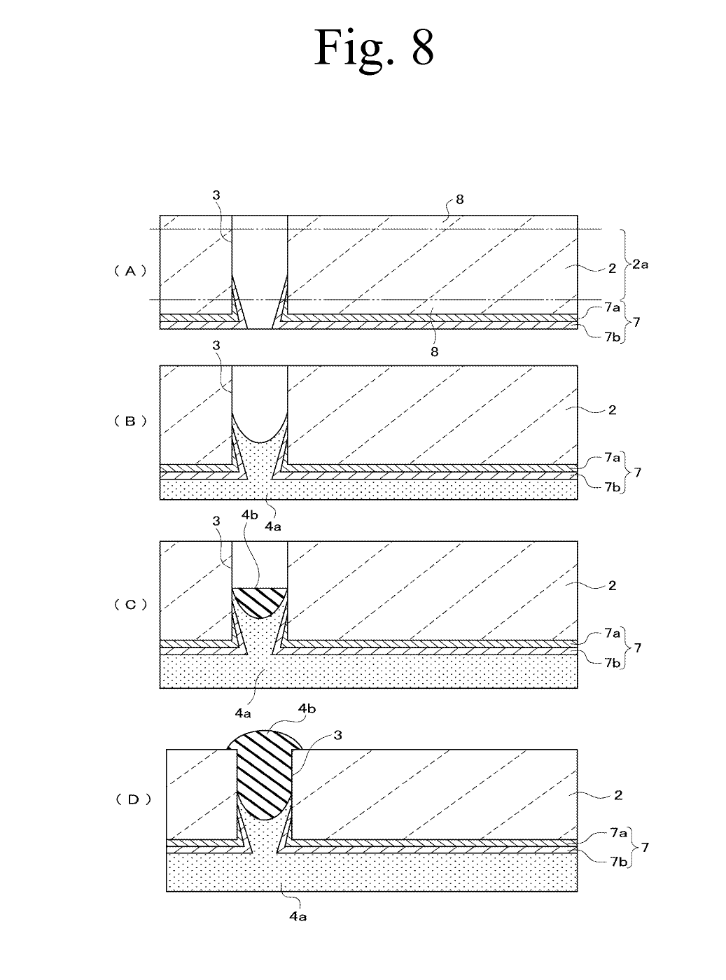

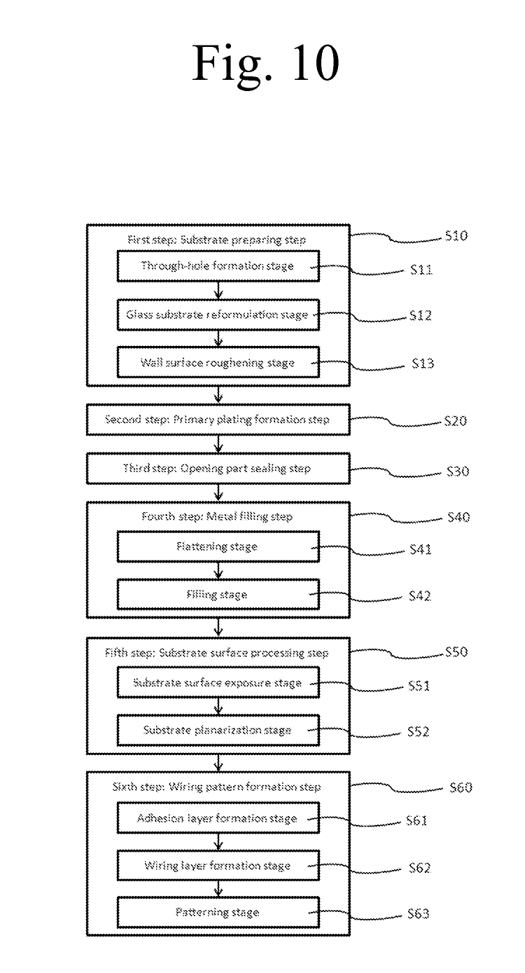

Hereinafter, a manufacturing method of a substrate and a manufacturing method of a wiring substrate according to the second embodiment of the present invention will be explained based on Figures. A flow chart according to the manufacturing method of the present embodiment is shown in FIG. 10 and a process chart according to the steps from the primary plating formation step S20 to a metal filling step S40 is shown in FIG. 8. Also, as shown in the flow chart of FIG. 10, the present embodiment is different from the first embodiment in that the forth step (metal filling step S40) is divided into a flattening stage S41 and a filling stage S42. Detailed explanation about other steps is omitted since they are the same as in the first embodiment.

The metal filling step S40 in the present embodiment is effective for the case where a shape of the surface (a sealed surface at the second surface side) in the through-hole 3 of the first plating layer 4a formed in the opening part sealing step S30 is a recess shape such as nearly a U-shaped or nearly a V-shaped cross sectional shapes in the center of the through-hole 3, as shown in FIG. 8B.

### (Forth Step: Metal Filling Step S40)

The metal filling step of the present embodiment includes the flattening stage S41 and the filling stage S42 as previously described. Hereinafter, each of the stages will be explained.

### (Flattening Stage S41)

In the flattening stage S41, as shown in FIG. 8B, a second plating layer 4b is formed using the electroplating on the bottom having the cross sectional recess shape composed of the first plating layer 4a formed in the through-hole 3 (specifically, nearly the U-shaped cross sectional shape or nearly the V-shaped cross sectional shape); thereby the bottom having the recess shape of the through-hole is flattened.

The electroplating in this flattening stage S41, that is, the electroplating for flattening the bottom of the through-hole 3 is performed using a so-called pulse reverse plating method. In the pulse reverse plating, a pulse plating is performed with applying a forward current having positive polar and a reverse current having negative polar alternately.

By performing the electroplating using such a technique, metal material constituting thick portion of the plating layer (for example, the vicinity of the top of the bottom having the recess shape) is electrolyzed and returns in electrolyte solution again; as a result, the plating layer can be formed on the portion on which metal material is hard to be deposited without thickening the plating layer on which metal material is easy to be deposited. Note that, details of the pulse reverse plating will be described later.

In the present embodiment, if a portion where the copper ions which is a base of the second plating layer 4b are easy to be concentrated exists in the bottom formed by the first plating layer 4a in the hole, intensive deposition of the copper ions on the portion is suppressed, because pulse plating using the pulse reverse plating is performed in the flattening stage S41. Specifically, when the bottom of the hole formed by the first plating layer 4a has the cross sectional recess shape, the copper ions are easy to be concentrated in the vicinity of the top of the cross sectional recess shape (uppermost part near the upper opening part side of the through-hole 3); however, the intensive deposition of the copper ions in the vicinity of the top of the cross sectional recess shape is suppressed while the copper constituting the second plating layer 4b is deposited inside the recess. Therefore, it is possible to avoid connecting with the copper each other which is deposited in the vicinity of the top of the cross sectional recess shape before filling the recess with the copper. In other words, it is possible to fill the recess with the copper without generating a void resulting from the recess; thereby flattening the bottom of the through-hole 3 with the second plating layer 4b as shown in FIG. 8C.

In the metal filling step S40, by performing the flattening stage S41 first, the bottom of the through-hole 3 is flattened once; thus even if the shape of bottom of the hole has any shape before the stage, it is possible to eliminate an influence of the shape of the bottom. More specifically, if the bottom of the through-hole 3 has the cross sectional recess shape, it is possible to prevent the void resulting from the recess from occurring.

### (Filling Stage S42)

After flattening the bottom of the hole in the flattening stage S41, subsequently, the filling stage S42 is performed. In the filling stage S42, as shown in FIG. 8D, the copper constituting the second plating layer 4b is deposited by the electroplating inside the through-hole 3 surrounded by the bottom of the hole flattened by the second plating layer 4b and the sidewall where the constituting materials of the glass substrate are exposed. Then, by growing the second plating layer 4b toward the upper opening part of the through-hole 3, the inside of the through-hole 3 is filled with the copper. After that, when the surface of the second plating layer 4b reaches the upper opening part of the through-hole 3, the through-hole 3 is completely filled with the second plating layer 4b. Herein, in order to ensure the filling of the through-hole 3 by the growth of the second plating layer 4b, as shown in FIG. 8D, the electroplating continues until the surface of the second plating layer 4b is projected toward upper surface side of the glass substrate 2.

With respect to the electroplating in this filling stage S42, that is, the electroplating for filling the inside of the through-hole 3, pulse plating using the pulse reverse plating method is effective in a similar way of the above flattening stage S41.

In the filling stage S42 included in the metal filling step S40 of the present embodiment, the inside of the through-hole 3 can be filled with the copper while the bottom of the hole is flat and the constituting materials of the glass substrate 2 are exposed on the sidewall. Therefore, in the filling stage S42, the copper can be uniformly deposited on the surface of the flat bottom with suppressing the local adhesion of the copper ions to the sidewall of the inside of the hole. This means that generation of the void inside the through-hole 3 can be avoided not only in the flattening stage S41 but also in the filling stage S42.

### [Control of the Electroplating]

Herein, control of the electroplating in the metal filling step S40 will be explained in detail.

### (Pulse Control)

In the metal filling step S40, as previously described, pulse plating using the pulse reverse plating method as the electroplating is performed. That is, in each of the flattening stage S41 and the filling stage S42, pulse plating in which the forward current having positive polar and the reverse current having negative polar are alternately applied, is performed.

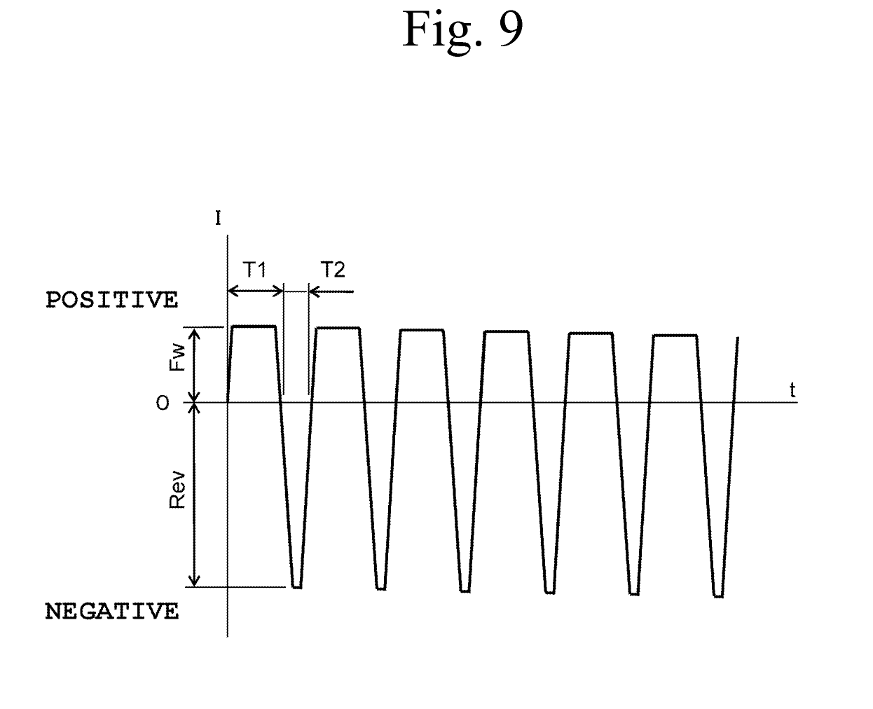

FIG. 9 is a timing diagram to explain the pulse reverse plating method according to the embodiment of the present invention. In the figure, the vertical axis represents a value of the current I which is applied between the anode and the cathode during the electroplating, the horizontal axis represents an elapsed time which represents a time change of the applied current by the pulse reverse plating method. More specifically, this represents the time change of the positive polar forward current and the negative polar reverse current against the elapsed time.

The term “the value of the current” here is specified by the value when applying the positive and negative constant current between the anode and the cathode. However, as described later, the value of the current does not need to be the constant value of the current, and may be specified by the value applied the constant voltage. In the present embodiment, a value of the forward current which is positive is defined as “Fw”; a value of the reverse current which is negative is defined as “Rev”, the following is explained with the example specified by these.

During the pulse plating using the pulse reverse plating method, as shown in FIG. 9, a pulse by forward current Fw which is positive and a pulse by reverse current Rev which is negative are alternately applied.

“Fw/Rev” showing a ratio of absolute values of the forward current Fw and the reverse current Rev is set within ranges of, for example, 1/1 to 1/5, preferably about 1/2 to 1/3. “T1/T2” showing a ratio of an applied time T1 of the pulse by the forward current Fw and an applied time T2 of the pulse by the reverse current Rev is set within ranges of, for example, 5/1 to 30/1, preferably about 20/1. Note that, T1 showing the time of one pulse is set to, for example, 0.1 sec to 5 sec. When the applied time T1 once is short, switching of the pulse frequently occurs; when the applied time T1 once is too long, the film quality of the plating layers may deteriorate; therefore, the time of one pulse T1 is preferably set within the above range.

According to such pulse control, a positive electrical quantity per one pulse (i.e. a value of time integration of the forward current Fw per one pulse) is larger than a negative electrical quantity per one pulse (i.e. a value of time integration of the reverse current Rev per one pulse). Therefore, even if the pulse plating in which positive and negative currents are alternately applied, is performed, the growth of the second plating layer 4b is ensured.

Note that, when applying the positive polar forward current, the pulse plating is performed under the condition that a current density is relatively low (for example, about 0.2 A/dm² to 0.8 A/dm²).

Also, it is important that an applied voltage is set to a hydrogen overvoltage or less when applying the positive polar forward current. The reason is that it is very difficult to remove hydrogen gas foam generated when the shape of the through-hole 3 has a high aspect ratio.

In such pulse plating process, during the application of the forward current, copper is deposited on the surface of the first plating layer 4a as the cathode.

On the other hand, during the application of the reverse current, the copper deposited once is absorbed back into the electrolyte solution. At this time, the copper is intensively disengaged from the vicinity of the top of the recess shape composed of the second plating layer 4b which is closest to opposite electrode; while the copper is hard to be disengaged from the portion except for the vicinity of the top.

Therefore, by performing the pulse plating in which the forward current and the reverse current are alternately applied, it becomes possible to deposit the copper on the portion where the copper is hard to be deposited, with suppressing the deposition of the copper on the specified portion. That is, it becomes feasible to suppress the variations in the degree of the deposition of the copper by each place.

### (Constant Current Control)

The electroplating with the pulse control using the above pulse reverse plating method can be performed by any one of a constant current method and a constant voltage method. In the constant current method, the electroplating is performed with the constant current. In contrast, in the constant voltage method, the electroplating is performed with the constant voltage.

In the case of the electroplating with the constant voltage method (hereinafter referred to as “constant voltage electroplating”), an amount of the flowing current becomes non-constant due to conditions of the solution and so on because the voltage is constant. For this reason, the deposition rate becomes hard to be regulated with time. Also, although it is possible to regulate the rate with the integral current, the current density changes, which may causes a problem in properties of the plating layers deposited.

In contrast to this, in the case of the electroplating with the constant current method (hereinafter referred to as “constant current electroplating”), it is possible to regulate an amount of deposition of the plating layers by time because the value of the current can be controlled at a constant value. Therefore, it never takes a long time to deposit the plating layers and the plating layers are never formed inhomogeneously.

The electroplating in the metal filling step S40 (i.e. the pulse plating using the pulse reverse plating) may be the constant current electroplating or the constant voltage electroplating. However, in the present embodiment, the constant current electroplating is preferable in view of the above reasons (i.e. quickness of the electroplating treatment, homogeneity of the plating layers to be formed and so on).

### Third Embodiment

The present embodiment is the embodiment according to a manufacturing method of substrate 2 with an area 9a where distribution density of the through-holes 3 shows sparse and an area 9b where distribution density of the through-holes 3 shows dense. First, a relation between formation state of the through-hole 3 and the electroplating which is most relative to the present embodiment will be explained. Note that, a detailed explanation in each of the steps will be omitted since a manufacturing method of the substrate according to the present embodiment includes the same steps as the steps of the second embodiment shown in FIG. 10.

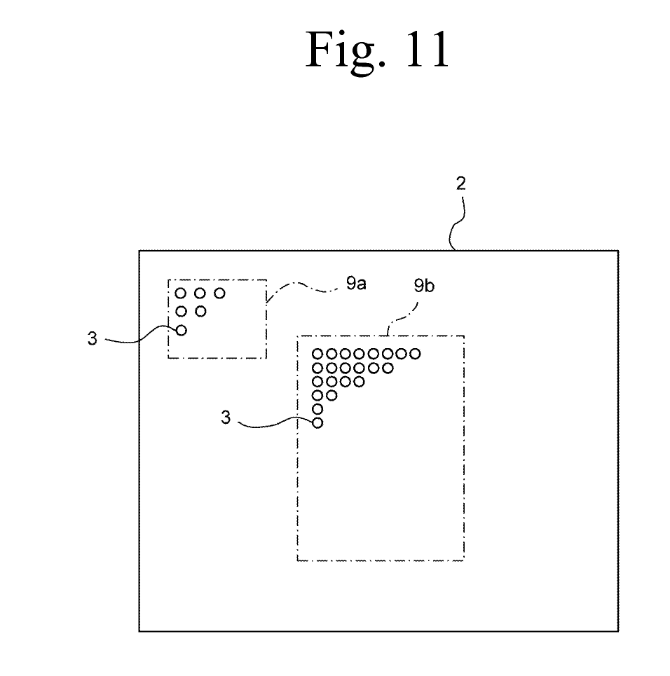

In the present embodiment, a plurality of the through-holes 3 to be filled with metal by the electroplating is formed on the glass substrate 2. On the glass substrate 2, the area 9a where the through-holes 3 are distributed sparsely and the area 9b where the through-holes 3 are distributed densely are in the mixed state (for example, referred to FIG. 11).

Even if the areas 9a, 9b where the distribution density of the through-holes 3 are different on the glass substrate 2 are in the mixed state, single or plural glass substrate 2 is regarded as one unit and the electroplating for filling the hole with metal is performed per the unit. That is, to each of the areas 9a, 9b on the glass substrate, the filling of the hole with metal by the electroplating is performed at the same time. Thus, if the areas 9a, 9b where the distribution density of the through-holes 3 are different on the glass substrate 2 are in the mixed state, the copper ions are easy to be concentrated in the holes on the area 9a where the through-holes 3 are distributed sparsely during the electroplating, compared with the area 9b where the through-holes 3 are distributed densely. This is because, in the area where the number of the holes per unit area is low, the copper ions are easier to be concentrated in the holes, compared with the area where the number of the holes per unit area is high.

This means that the following relation holds. That is, the area 9a where the through-holes 3 are formed with sparse distribution on the glass substrate 2 corresponds to an area where the through-holes 3 are formed with the state where the copper ions which are a base for the second metal materials constituting the second plating layer, are easy to be concentrated (hereinafter referred to as “ion concentration area”). Also, the area 9b where the through-holes 3 are formed with dense distribution on the glass substrate 2 corresponds to an area where the through-holes 3 are formed with the state where the copper ions which are a base for the second metal materials constituting the second plating layer, are hard to be concentrated (hereinafter referred to as “ion dispersion area”). Note that, “the state where the copper ions are easy to be concentrated in the hole” in the ion concentration area 9a and “the state where the copper ions are hard to be concentrated in the hole” in the ion dispersion area 9b mean that whether the copper ions is easy to be relatively concentrated or not comparing the area 9a with the area 9b.

In the present embodiment, as explained in the first embodiment, in the primary plating layer formation step S20, the primary plating layer is formed at the position of the backward of the through-hole 3 beyond the lower opening part of the through-hole 3. Thus the through-hole 3 becomes the hole having thick bottom by the first plating layer 4a in the opening part sealing step S30. From the upper opening part to the bottom, the hole becomes shallow thus the metal ions are easy to go into the hole. Therefore, the metal ions are provided inside the through-hole 3 formed in the area 9b where the copper ions are hard to be concentrated; thereby distribution of the metal ions due to the formation state of the through-hole is hard to occur.

Further, in the present embodiment, for each of the areas 9a, 9b, the pulse plating using the pulse reverse plating method is employed as the electroplating for filling the hole with metal in the metal filling step S40, in a similar way of the above second embodiment. Therefore, even if the ion concentration area 9a and the ion dispersion area 9b are in the mixed state on the glass substrate 2, the degree of filling with the copper inside the through-holes 3 respectively in each of areas 9a, 9b is equalized.

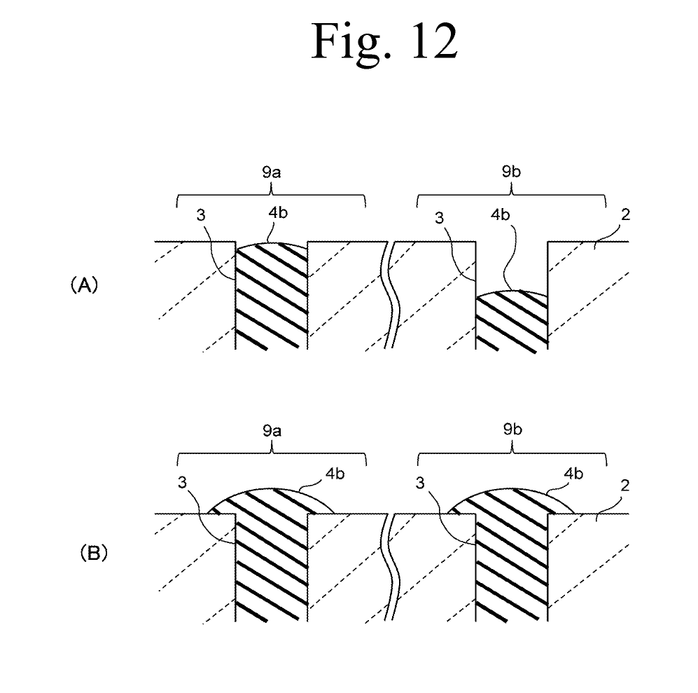

More specifically, if the ion concentration area 9a and the ion dispersion area 9b are in the mixed state on the glass substrate 2, the copper ions are easy to be concentrated inside the through-hole 3 in the ion concentration area 9a; as a result, as shown in FIG. 12A, the growth of the second plating layer 4b in the ion concentration area 9a may be faster than that in the ion dispersion area 9b. However, even in the above case, by performing the pulse plating using the pulse reverse plating method, intensive adhesion of the metal ions do not occur inside of particular through-hole 3 on the glass substrate 2. That is, even if the area 9a and the area 9b are in the mixed state, concentration of ions is suppressed inside of the through-hole 3 in the ion concentration area 9a. Therefore, when the second plating layer 4b is grown until the through-hole 3 is completely filled, as shown in FIG. 12B, the degree of filling with the copper inside the through-holes 3 respectively in each of areas 9a, 9b is equalized.

In this way, in the present embodiment, by performing the pulse plating using the pulse reverse plating method, the degree of filling the hole with the copper is equalized; therefore, variations in the degree of filling the hole with the copper in each of areas 9a, 9b can be avoided. This holds true for each through-hole 3 in the same area as well as the through-holes 3 in each of the areas 9a, 9b. That is, by performing the pulse plating using the pulse reverse plating method, with respect to each of the plural through-holes 3 on the glass substrate 2, variations in the degree of filling the hole with the copper can be avoided.

Furthermore, the above avoidance of the variations can be realized by performing the pulse plating using the pulse reverse plating method only in the metal filling step S40. That is, for example, without performing such complicated treatment as changing treatment conditions in each of the areas 9a, 9b, it is possible to control automatically the degree of filling the hole with the copper inside the through-holes 3.

Also, all of the plural through-holes 3 provided on the glass substrate 2 have no need to be placed by equal pitch and various ways of placements of the holes are accommodated flexibly since the degree of filling with the copper inside each of the through-holes 3 is equalized. Therefore, in the present embodiment, versatility of placement pattern of the through-holes 3 on the wiring substrate 1 can be fully ensured, which is highly suitable for configuring the wiring substrate 1.

Note that, in the present embodiment, the case where distribution density of the through-holes 3 is different in each of the areas 9a, 9b is exemplified, however, as explained in aforementioned “variation, modification and so on”, the present invention is not limited to the case.

### (Variation, Modification and So On)

Note that, the technical scope of the present invention is not limited to the above embodiments, and includes embodiments with various modifications and improvements as far as specific effects obtained. by constituent features of the invention and combination thereof are derived.

For example, in the above-mentioned first to third embodiments, the manufacturing method of the wiring substrate are explained, however, the present invention is not limited to the embodiments and can be realized by a manufacturing method of substrate utilized as an application except for the wiring substrate.

Also, in the above-mentioned first to third embodiments, the glass substrate having photosensitive property is used as the glass substrate 2; however, other glass substrate having no photosensitive property may be used. In this case, in the through-hole formation step, the through-hole 3 can be formed on the glass substrate by the method except for the photolithography method, for example, laser machining method.

Also, in the above third embodiment, the case in which the distribution density is different between the ion concentration area 9a and the ion dispersion area 9b is exemplified; however the ion concentration area 9a may be an area where the through-holes 3 having a large diameter are formed, the ion dispersion area 9b may be an area where the through-holes 3 having a small diameter are formed. The size of diameters herein is relative between the area 9a and the area 9b; the values of the diameter are not limited. When such areas 9a, 9b are in the mixed state, the copper ions are easier to be concentrated inside the holes having a large diameter formed on the ion concentration area 9a during the electroplating, compared with the ion dispersion area 9b where the through-holes 3 having a small diameter are formed. This is because the copper ions are easier to go into the hole having a large diameter compared with the hole having a small diameter. However, with respect to both the area 9a and the area 9b, the pulse plating using pulse reverse plating method is performed; the degree of filling with metal the through-holes 3 having each large and small diameter is equalized since the ion concentration inside the through-holes 3 having a large diameter is suppressed. Therefore, as described in the above, with respect to the plural through-holes 3 provided on the glass substrate 2, all of these have no need to be formed at same size; it becomes possible to accommodate various diameters flexibly; thus versatility of diameter sizes of the through-holes 3 in the wiring substrate 1 is fully ensured, which is quite suitable for configuration of the wiring substrate 1.

This holds true for a case where the ion concentration area 9a and the ion dispersion area 9b are in the mixed state due to the other state. That is, even if there is other state except for the variation of distribution of the through-holes 3 and the size of the through-holes 3, the manufacturing method of the present invention is applicable to the case where the ion concentration area 9a and the ion dispersion area 9b are in the mixed state.

1. A manufacturing method of a substrate comprising the steps of:
a first step of preparing a glass substrate comprising a plate glass base material having a first surface and a second surface which have a relation of front and rear surfaces, wherein one or more through-holes having a first opening part at a first surface side and a second opening part at a second surface side is formed on said glass substrate;
a second step of forming a primary plating layer composed of metal on the first surface side of the glass substrate;
a third step of sealing the first opening part of said through-hole with a first metal material by forming a layer of the first metal material using an electroplating on the first surface side of said glass substrate; and
a fourth step of filling said through-hole with metal by depositing a second metal material in said through-hole using the electroplating from the second surface side of said glass substrate, wherein
in said second step, said primary plating layer is formed on from an edge of the first opening part of said through-hole to a part of sidewall surface of said through-hole;
in said third step, the first opening part of said through-hole is sealed with said first metal material by growing a layer consisting of said first metal material from a surface of said primary plating layer inside of said through-hole; and
in said forth step, said through-hole is filled with metal by growth of said second metal material in plating from a surface of said first metal layer inside said through-hole toward the second opening part of said through-hole.

2. The manufacturing method of the substrate as set forth in claim 1, wherein
in at least a part of said forth step, a pulse plating in which a forward current having a positive polar and a reverse current having a negative polar is alternately applied, is performed as said electroplating.

3. The manufacturing method of the substrate as set forth in claim 2, wherein
in said pulse plating, the reverse current at a predetermined value is applied after the forward current at a predetermined value is applied.

4. The manufacturing method of the substrate as set forth in claim 2, wherein
said fourth step includes a flattening stage in which a sealed surface at the second surface side of the first opening part sealed in the third step is flattened by said second metal material; and
in at least the flattening stage, said pulse plating is performed.

5. The manufacturing method of the substrate as set forth in claim 2, wherein
said fourth step includes a filling stage in which an inside of the through-hole surrounded by the sealed surface at the second surface side of the first opening part sealed in the third step and a sidewall on which a constituting material of said glass substrate is exposed, is filled by depositing said second metal material in said hole, and
in at least the filling stage, said pulse plating is performed.

6. The manufacturing method of the substrate as set forth in claim 4, wherein
said fourth step includes a filling stage in which an inside of the through-hole surrounded by the sealed surface at the second surface side of the first opening part sealed in the third step and a sidewall on which a constituting material of said glass substrate is exposed is filled by stacking said second metal material in said hole, and
in at least the filling stage, said pulse plating is performed.

7. The manufacturing method of the substrate as set forth in claim 2, wherein
in said first step, the glass substrate with a plurality of said through-holes formed, having an area where said through-holes are distributed sparsely and an area where said through-holes are distributed densely, is prepared.

8. The manufacturing method of the substrate as set forth in claim 2, wherein
in said first step, the glass substrate on which more than one kind of the through-holes having different shapes from each other at a vertical cross section in a communicated direction thereof, is prepared.

9. The manufacturing method of the substrate as set forth in claim 1, wherein
in said first step, the glass substrate having the through-hole whose shape at a vertical cross section is a flared shape in a communicated direction thereof at a first opening part side is prepared.

10. The manufacturing method of the substrate as set forth in claim 1, wherein said first metal material and said second metal material are the same metal material.

11. The manufacturing method of the substrate as set forth in claim 1, wherein said first metal material and said second metal material are composed of a metal constituted by one or an alloy constituted by two or more selected from copper, nickel, gold, silver, platinum, palladium, chromium, aluminum and rhodium.

12. A manufacturing method of a wiring substrate, wherein after a substrate in which a through-hole of a glass substrate is filled with a metal material is manufactured by the manufacturing method as set forth in claim 1, a wiring is formed on at least one of one surface side and the other surface side of the glass substrate.
